(19) United States
(12) Patent Application Publication
(10) Pub. No.: US 2014/0293679 A1
(43) Pub. Date: Oct. 2, 2014

(54) MANAGEMENT OF SRAM INITIALIZATION

(71) Applicant: INTERNATIONAL BUSINESS MACHINES CORPORATION, Armonk, NY (US)

(72) Inventors: Derick G. Behrends, Rochester, MN (US); Todd A. Christensen, Rochester, MN (US); Michael W. Harper, Round Rock, TX (US); Travis R. Hebig, Rochester, MN (US); Michael Launsbach, Rochester, MN (US)

(73) Assignee: International Business Machines Corporation, Armonk, NY (US)

(21) Appl. No.: 13/850,370

(22) Filed: Mar. 26, 2013

(51) Int. Cl. G11C 11/4072

(52) U.S. Cl. CPC G11C 11/4072
USPC 365/154

(57) ABSTRACT

An embodiment of the current disclosure is directed to a Static Random Access Memory (SRAM) device, and a design structure for the SRAM device. The SRAM device may include one or more SRAM cells. Each SRAM cell may further include a first and a second CMOS inverter that are cross-coupled. The first and second CMOS inverters may each have a first switch and a second switch. The SRAM device may also include a reset circuit. The reset circuit may be coupled to a first node of the first switch of the first CMOS inverter. The reset circuit may drive the first CMOS inverter to output a logical high signal in a reset mode.

### TECHNICAL FIELD

The present disclosure relates to a static random-access memory (SRAM). In particular, this disclosure relates to initializing one or more SRAM cells in an SRAM device.

### BACKGROUND

SRAM memory cells may need to be set to a particular state at startup, such as a zero state, which may be beneficial in some applications such as testing. The process of setting SRAM cells at startup or reset is referred to as initialization. SRAM cells may be initialized individually or throughout an entire memory bank with a memory bank including one or more SRAM cells.

### SUMMARY

Embodiments of the disclosure provide a device, and a design structure for initializing a Static Random Access Memory (SRAM) device.

One embodiment of the current disclosure is directed to an SRAM device. The SRAM device may include one or more SRAM cells. Each SRAM cell may further include a first and a second CMOS inverter that are cross-coupled. The first and second CMOS inverters may each have a first switch and a second switch. The SRAM device may also include a reset circuit. The reset circuit may be coupled to a first node of the first switch of the first CMOS inverter. The reset circuit may drive the first CMOS inverter to output a logical high signal in a reset mode.

Another embodiment may be directed to a design structure tangibly embodied in a machine-readable storage medium used in a design process of an SRAM device. The design structure may have elements that produce, when processed in a semiconductor manufacturing facility, an SRAM device that includes one or more SRAM cells coupled to each other. Each SRAM cell may further include a first and a second CMOS inverter that are cross-coupled. The first and second CMOS inverters may each have a P-channel Field Effect Transistor (PFET) and an N-channel Field Effect Transistor (NFET). The design structure may have a reset circuit coupled to a first node of the NFET in the first CMOS inverter of the one or more SRAM cells. The reset circuit may drive a reset output to the first CMOS inverter to a reset mode in order to reset the SRAM cell and may drive a normal mode to maintain operation of the SRAM cell.

Another embodiment may be directed to a Static Random Access Memory (SRAM). The SRAM may include one or more SRAM cells. The SRAM cell may further include a first CMOS inverter having a first N-type Field Effect Transistor (NFET) and a first P-type Field Effect Transistor (PFET). The NFET may have a first node and a second node. The PFET may have a first node and a second node. The second node of the first NFET may be coupled to the second node of the first PFET. The first node of the PFET may be coupled to a power supply such as Vdd. A gate of the first NFET may be coupled to a gate of the first PFET. The SRAM may also include a second CMOS inverter having a second NFET and a second PFET. A gate of the second NFET and a gate of the second PFET may couple to the second node of the first NFET. An output of the second CMOS inverter may be connected to the gate of the first NFET. The SRAM may also include a reset circuit to couple with the first node of the first NFET. The reset circuit may couple the first node of the first NFET to a power supply such as Vdd in a reset mode and may couple the first node of the first NFET to GND in a normal mode.

### BRIEF DESCRIPTION OF THE DRAWINGS

The drawings included in the present application are incorporated into, and form part of, the specification. They illustrate embodiments of the present invention and, along with the description, serve to explain the principles of the invention. The drawings are only illustrative of embodiments of the invention and do not limit the invention.

FIG. 1 is a schematic representation of a portion of a prior art SRAM device.

FIG. 2 is a waveform diagram of the prior art SRAM device of FIG. 1.

FIG. 3 is a schematic representation of a portion of an SRAM device that includes a column of SRAM cells, according to an embodiment.

FIG. 4 is a flowchart of a triggering mechanism for a reset mode of an SRAM device, according to an embodiment.

FIG. 5 is an analog waveform of an SRAM device, according an embodiment.

FIG. 6 is a digital signal waveform of an SRAM device, according to an embodiment.

FIG. 7 is a flow diagram of a design process used in semiconductor design, manufacture, and/or test of an SRAM device, according to an embodiment.

In the drawings and the Detailed Description, like numbers generally refer to like components, parts, steps, and processes.

### DETAILED DESCRIPTION

During testing of semiconductor devices, e.g., memory devices, it is typical to initialize all memory cells to a known value prior to testing the logic of the memory cells and the surrounding logic. The number of memory cells required to be initialized may range from millions to billions on an integrated circuit chip. In order to uniformly initialize all of the memory, all of the respective memory cells may need to be written, which may take thousands to millions of clock cycles. This initialization costs testing time which may be very expensive in a high volume chip.

This disclosure may concern the initialization of one or more memory cells, e.g., SRAM cells, in a memory device to a known state. The present disclosure may involve coupling a reset circuit to a GND of an inverter of an SRAM cell, specifically a first node of an N-channel Field Effect Transistor (NFET) of the inverter. The reset circuit may couple a GND, Vdd, or floating signal to the SRAM inverter which may initialize one or more SRAM cells. An aspect of this disclosure may concern reducing the competing leakage effects from the transistors in the memory cell. Prior art designs may concern driving a node of a p-channel Field Effect Transistor (PFET) low from one of the cross-coupled inverters from one or more SRAM cells.

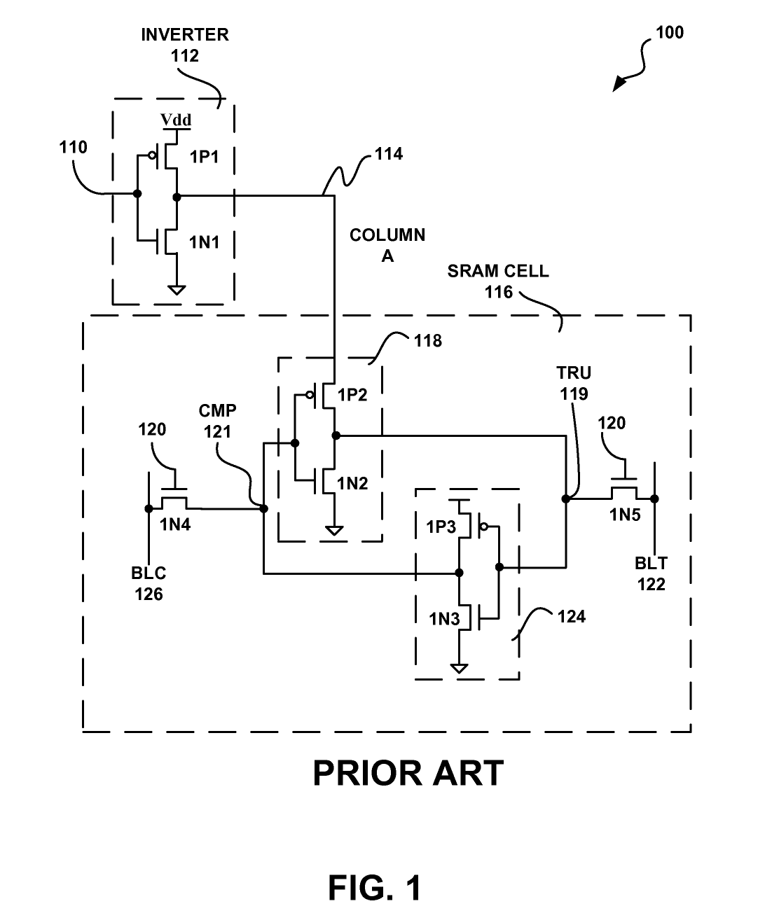

FIG. 1 illustrates a schematic of a prior art SRAM device 100, according to an embodiment. In the SRAM device 100, an inverter input 110 is received by an inverter 112. The inverter 112 may have a P-channel field effect transistor (PFET), 1P1, and an N-channel field effect transistor (NFET), 1N1. The inversion of the inverter input 110 may form an initialization input 114 for the SRAM cell 116 and may be transmitted to one or more SRAM cells along column A. In an embodiment, the initialization input 114 may be in a high state, meaning that the voltage corresponds to Vdd, or the initialization input 114 may be in a low state, meaning that the voltage corresponds to ground, or Vss. Under regular operation, i.e., a normal mode, of the SRAM device 100, the initialization input 114 may be driven to a high state. During initialization, i.e., a reset mode, the initialization input 114 may be driven to a low state.

The SRAM cell 116 may contain two inverters 118, and 124, in a cross-coupled configuration. Inverter 118 may have a PFET 1P2, with a first node and a second node, the second node may be connected to an NFET 1N2. Inverter 124 may have a PFET 1P3, and an NFET 1N3. The output of inverter 118 may have a true (TRU) node 119 and the output of 124 may have a complement (CMP) node 121. The two inverters 118, and 124 may also be connected to the two NFETS, 1N4 and 1N5. The input 114 may be connected to the inverter 118, specifically a source of 1P2. The term source and first node may be used interchangeably for the embodiment for the normal mode. However during the reset mode, the first node may be a drain. In an embodiment, column A may connect the inverter 112 to the first node of 1P2. Column A may transfer the initialization input 114 from the inverter 112 to one or more SRAM cells.

The 1N2 of the inverter 118 may be coupled to a ground. The inverter 118 may be coupled to CMP 121. TRU 119 may be connected to 1N5, and may be activated by a wordline (WL) 120. 1N5 may also receive a signal from a bit line TRU (BLT) 122. 1N4 may connect with CMP 121. The 1N4 may be activated by a signal from the WL 120 and connect to bit line complement (BLC) 126 in a similar manner to 1N5.

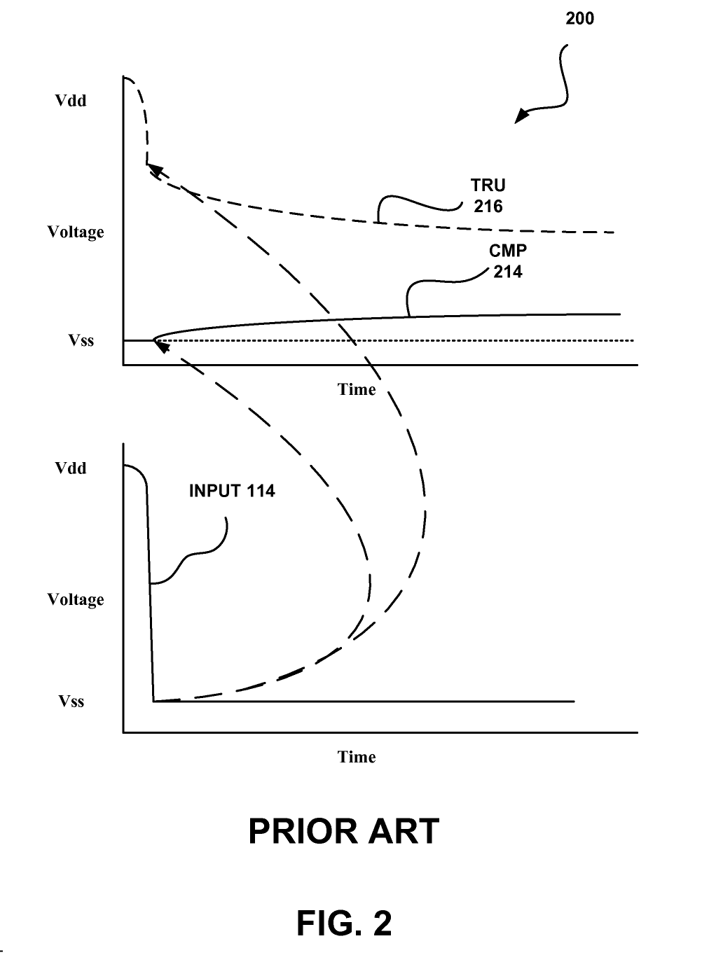

FIG. 2 illustrates a waveform diagram 200 depicting the relationship between the initialization input 114 and the CMP signal 214 and the TRU signal 216. The CMP signal 214 and the TRU signal 216 may correspond to the CMP121 and TRU 119 nodes from FIG. 1.

The waveform diagram 200 is shown as an output of a simulation that includes a random dopant-induced process variation. In the simulation, the dopant used in the NFETs and PFETs of FIG. 1, may be chosen to model a typical amount of random dopant variation onto the waveform diagram 200. The random variation produces varying strength PFET and NFET currents. Other simulations, e.g., a simulation including systematic variation, may produce a similar waveform diagram to waveform diagram 200.

As an initial state, or normal mode, the initialization input 114 may be driven high. The Vdd on 1P1 may be coupled to the Vdd on 1P2 in this initial state. The mentioned configuration would represent a normal mode.

In an initialization operation, or reset mode, for the SRAM device 100, the initialization input 114 would transition from high, i.e., Vdd, to low, i.e. a zero, ground, or Vss. By transitioning low at the initialization input 114, a low signal occurs at 1P2 on inverter 118. The low signal causes the TRU 119 to be low. In an embodiment, WL 120 of 1N4 and 1N5 are low. Since WL 120 is low, 1N4 and 1N5 are deactivated and BLT 122 is not connected with TRU 119 and BLC 126 is not connected with CMP 121.

If the TRU is low and there is an absence of current coming from 1N5, then the inverter 124 may invert the signal from TRU 119 to high which would make the CMP signal 214 high. Once the initialization input 114 returns to normal operation, i.e., goes from low to high, then the initial state where TRU 119 is low and CMP 121 is high is preserved through the cross-coupled connection between inverters 118 and 124.

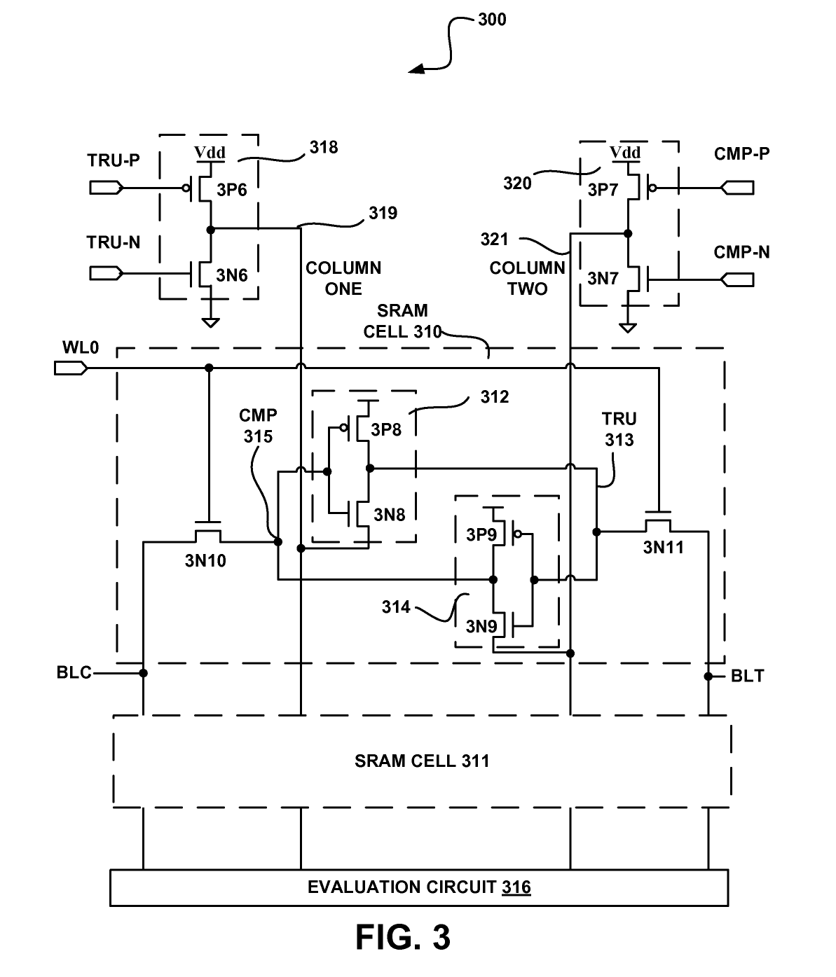

FIG. 3 illustrates a schematic representation of a SRAM device 300 that has one or more SRAM cells starting with SRAM cell 310, according to an embodiment. The SRAM device 300 is shown with two SRAM cell, 310, 311 but different number of SRAM cells in a SRAM device 300 are contemplated. In an embodiment, the SRAM device 300 may be referred to as an SRAM, or SRAM device.

The SRAM cell 310 may be in a cross-coupled configuration with two inverters, 312 and 314. Inverter 312 includes PFET 3P8 (with a first node connected to Vdd and a second node connected to NFET 3N8) and NFET 3N8 (with a second node connected to PFET 3P8 and a first node connected to 318). In some embodiments, 3N8 and 3P8 may be referred to as a first switch and second switch, respectively. Inverter 314 includes PFET 3P9 with a first node connected to Vdd and a second node connected to NFET 3N9 and NFET 3N9 with a first node connected to inverter 320 and a second node connected to PFET 3P9. During a normal mode, the first node of 3N8 may be a source. During a reset mode, the first node of 3N8 may be a drain. The inverter 312 may output a signal to the TRU 313 and may also be referred to as the TRU inverter. The output of inverter 312 may be coupled to the input, specifically a control gate or gate, of inverter 314. The inverter 314 may output a signal to CMP 313. Inverter 314 may also be coupled to the input, specifically a control gate or gate, of inverter 312. Inverter 314 may also be referred to as the CMP inverter.

NFET 3N10 may couple with the output of inverter 314 and to a bit line CMP (BLC). NFET 3N11 may couple with the output of inverter 312 and a bit line TRU (BLT), which may further lead to the evaluation circuit 316. BLT and BLC may be further coupled to the evaluation circuit. The wordline WL0 may provide the control to both 3N10 and 3N11. During an initialization state, or a reset mode, the WL0 may be deactivated.

3N8 may be coupled to inverter 318 via at the source, or first node, of 3N8. In some embodiments, inverter 318 may be a tri-state inverter. Inverter 318 may be referred to as the reset circuit. Inverter 318 may have a PFET 3P6 and NFET 3N6. 3P6 may receive a control signal from TRU-P. 3N6 may receive a control signal from TRU-N. In another embodiment, inverter 318 may be an ordinary inverter where gates of 3P6 and 3N6 are connected together to a single input so that the inverter 318 always drives either Vdd or GND to column one 319. The output of inverter 318 may lead to column one 319, according to an embodiment. Column one 319 may further couple to the first node of 3N8. In the shown embodiment, column one may also couple to the first inverter, e.g., 312 of one or more SRAM cells, e.g., SRAM cell 310, and SRAM cell 311 and may couple to an evaluation circuit 316, according to an embodiment. In other embodiments, column one 319 does not couple to an evaluation circuit 316.

The first node of 3N9 may be coupled to an inverter 320. The inverter 320 may have a PFET 3P7 and a NFET 3N7. In an embodiment, the inverter 320 may be a tri-state inverter. 3P7 may receive a control signal on its gate from CMP-P. 3N7 may receive a control signal on its gate from CMP-N. The output of inverter 320 be referred to as column two 321. Column two may be coupled to one or more SRAM cells, e.g., SRAM cell 311, in a similar manner to in column one. Column one and column two may be in a high, low, or floating state.

Inverter 318 and inverter 320 are both shown as tri-state inverters, but other configurations are possible. The input to the tri-state inverter 318 is shown as having independent inputs TRU-P, and TRU-N, but may also have logic that relies on one or more inputs. A similar configuration may exist with inverter 320. The output of inverters 318 and 320, may be floating, a high signal, or a low signal. The inverters 318 and 320 may act independently or in conjunction with each other, according to an embodiment. The tri-state inverter 318, may have advantages, for example, in power gating applications. In a power gating application, inverter 318 and inverter 320 may be held in a floating state by a memory controller to minimize leakage current and save power within the SRAM cell. The inverters 318 and 320 may be used to perform a power saving function, or power saving mode, in addition to performing a reset operation.

In an embodiment, the signal at column one 319 and column two 321 may be the inverse of each other in an initialized state, i.e., if column one is high, then column two is low. In a normal mode, both column one and column two may be driven low. During initialization, or the reset mode, column one 319 may be driven high, and then the high signal may be transmitted to the first node of 3N8 on inverter 312. The high signal may initiate the reset mode, according to an embodiment.

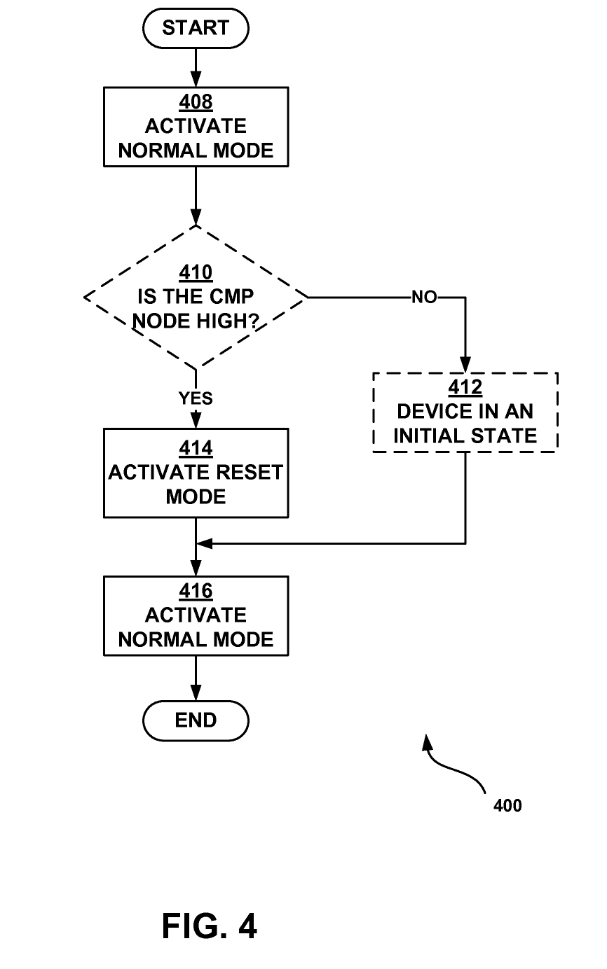

A reset configuration, or reset mode, of the SRAM cell 310 may occur when column one 319 is driven high (further described in FIG. 4). When column one 319 is driven high(to Vdd) in a reset mode, the SRAM cell 310 is configured to force a high signal at TRU 313. That is, if TRU 313 is “0”, CMP 315 is “1”, when column one 319 rises, the first node of 3N8 becomes a drain of 3N8; 3N8 has a “1” as gate input and pulls TRU 313 upwards to an NFET threshold below Vdd, causing inverter 314 to pull CMP 315 downwards, thereby turning on 3P8 to assist in further driving TRU 313 to a “1”. When 3N8 is driven low under a normal configuration, or a normal mode, then the SRAM cell 310 may maintain a low signal at CMP 315 no matter what state the SRAM cell 310 was in prior to the reset mode.

If the SRAM cell is required to be in a low, or zero state, then a similar operation to that described above may occur with column two. For example, a high state at column two 321 may cause a high signal across 3N9 on inverter 314. The high signal from 3N9 may cause CMP 315 to be high which may cause the value at TRU 313 to be low. Once the signal at column two 321 is driven from high to low, then SRAM cell 310 may hold the zero state.

In some embodiments, logic or initialization patterns may be created on one or more SRAM cells 310. For example, an entire bank of SRAM cells may be high while an adjacent bank is driven low. There may also be variations within a bank of SRAM cells, e.g., a “checkerboard pattern”. The checkerboard pattern may occur, if, e.g., within a bank of SRAM cells, every even SRAM cell is driven low and every odd SRAM cell is driven high as an initialization state. The checkerboard pattern may be produced if a memory bank is wired so that column one is connected to a TRU inverter in every odd SRAM cell and column one is connected to a CMP inverter in every odd SRAM cell in the memory bank.

FIG. 4 illustrates a flowchart of a triggering mechanism 400 for activating the reset mode of the SRAM device 300 in FIG. 3, according to an embodiment. The triggering mechanism 400 may describe when the reset mode is activated relative to the normal mode. Even though the triggering mechanism 400 is described in reference to inverter 318 initializing the SRAM device 300, a similar triggering mechanism may occur with inverter 320. The triggering mechanism 400 may begin at operation 408. In operation 408, the SRAM device 300 may be in a normal mode. The normal mode may correspond with coupling the first node of inverter 312 to the GND of inverter 318. After operation 408, the triggering mechanism 400 may proceed to operation 410. In operation 410, the CMP 315 may be in a high or a low initial state. If the CMP 315 is in a low initial state, then the operation 410 may proceed to operation 412. In operation 412, the inverter 312 may output a high state if the CMP 315 is in a low state. Therefore, the TRU 313 may be high and the CMP 315 may be low. The operation may proceed to operation 416. In operation 416 the normal mode may be activated. Operation 410, and operation 412 may be optional or may not need to be monitored. In another embodiment, operation 410 may be established by a feedback logic where the feedback logic connects to the triggering mechanism 400.

If the CMP 315 is in a high state, then operation 410 may proceed to operation 414. In operation 414, the reset mode may be initiated. The reset mode may be initiated using a signal that signals that, e.g., the SRAM device 300 needs to be initialized in a startup operation. The high signal at CMP 315 may cause the gate at 3N8 to connect Vdd from inverter 318 to the first node, which may become the drain. The source of 3N8 may have a lower potential than the drain. Therefore, in the rest mode, the source of 3N8 would be the second node and the drain of 3N8 would be the first node. A high signal received by 3N8 at the first node may cause the TRU 313 to approach Vdd-Voltage Threshold for an NFET (VTN). The CMP 315, or gate node, may have a voltage threshold that is above the source node in order for 3N8 to conduct.

After the TRU 313 is driven to Vdd-VTN, the TRU 313 may be aided by current leakage at 3P8, according to an embodiment. PFET 4P10 may contribute leakage toward Vdd even before CMP 315 exceeds Vdd-VTP (where VTP is a PFET threshold). In the described configuration, the wordline WL0 may be low which may cause 3N10 and 3N11 to be disabled. There may be other configurations where the wordline WL0 may allow different actions on 3N10 and 3N11. Current leakage may also occur across 3N11 which may further strengthen the high signal at TRU 313. The high signal at TRU 313 may cause the inverter 314 to produce a low signal at CMP 315.

After the CMP 315 is driven low. The gate of 3P8 may be held low which may cause 3P8 to conduct the Vdd at the first node of 3P8. The SRAM device 300 may hold a high signal at TRU 313 and a low signal at CMP 315.

The initiation of the reset mode may occur by default, meaning that operation 410, and operation 412 may be optional, according to an embodiment. For example, if the reset mode is activated when CMP 315 is in a low state, then the first node, i.e., Vdd, of PFET 3P8 may be selected. Leakage at 3N8 may not occur if the Vdd at 3P8 is activated and Vdd from column one 319 is received by 3N8 due to a lack of potential difference between the source and the drain of 3N8.

After operation 414, the triggering mechanism 400 may proceed to operation 416. Operation 416 may activate the normal mode. Operation 416 may be initiated using timing. For example, the normal mode may be activated every 4 cycles after the reset mode is initiated. In another embodiment, the normal mode may be activated using gating logic to trigger the normal mode at the inverter 318 if the CMP produces a low signal. After the normal mode is initiated in operation 416, then the triggering mechanism may end.

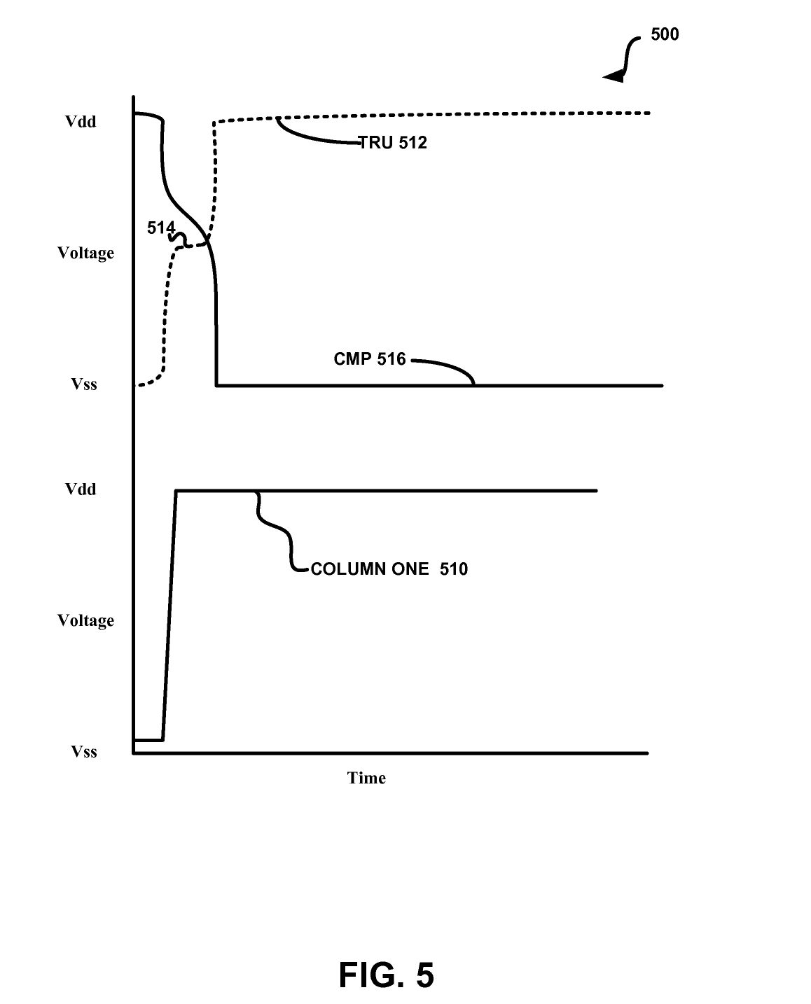

FIG. 5 illustrates a wave form diagram 500 that shows the effect of the column one signal on the TRU 313 and CMP 315 of FIG. 3, according to an embodiment. The column one signal 610 may correspond to initialization input 319 on FIG. 3. The column one signal 510, may travel through 3N8 by a gate signal from CMP 315. The TRU signal 512 may be the signal at TRU 313 on FIG. 3. As the voltage is increased to Vdd at column one 610, the TRU initially needs to overcome the VTN of 3N8 (as described in FIG. 4) and has only a small increase in voltage at Vdd-VTN 514.

A small increase in voltage as the TRU 313 approaches Vdd-VTN 514 may lead to a higher voltage from the CMP signal 516 at the CMP 315. A small increase in the voltage at inverter 314 may activate the gate at 3N9. This may lead to a low CMP signal 516. As the voltage decreases exponentially toward Vss at the CMP signal 516, the TRU signal 512 goes high as it is inverted by inverter 312. At inverter 314, two current paths from the inverter 312 and the leakage current across 3N11 may be combined to produce a low signal 516 at CMP 315.

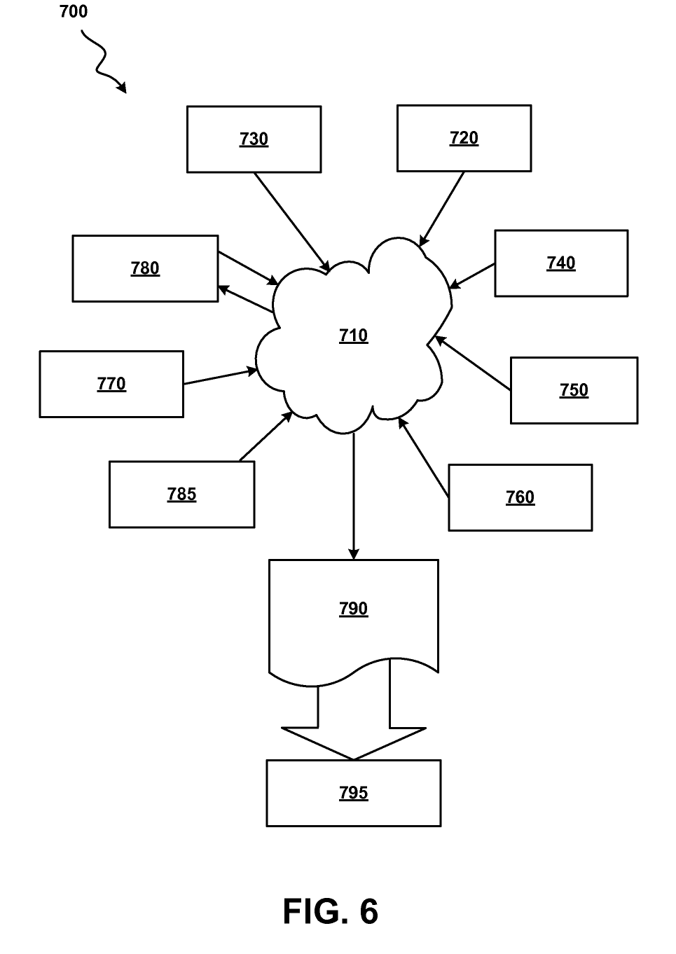

FIG. 6 illustrates a digital timing diagram 600 that illustrates the operation of an SRAM cell, according to an embodiment. The digital diming diagram 600 may relate to the hardware embodiments in the SRAM cell 310 in FIG. 3 and analog timing diagram 500 in FIG. 5. In the shown embodiment, a column one signal 610 may be driven high for a short time, while the column two signal 612 may be driven low. The high column one signal 610 may cause the TRU signal 614 to increase from Vss to Vdd, in a similar manner to the embodiment in FIG. 5. If the TRU signal 614 was already at Vdd prior to initialization, then the column one signal 610 may allow TRU 614 to remain at Vdd.

The TRU signal 614 may be inverted by inverter 314 and the CMP signal 616 may be driven low if the TRU signal 614 is high. As column one is driven low to Vdd, then the inverter 312 may hold the state.

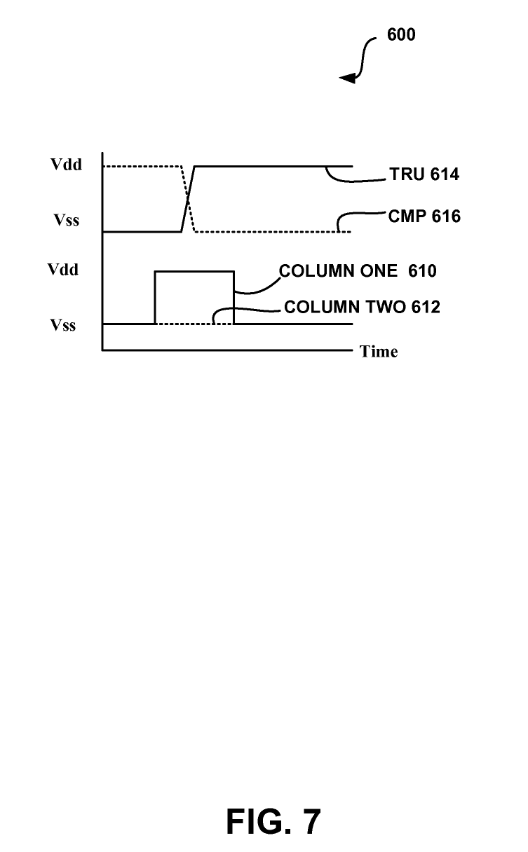

FIG. 7 illustrates multiple design structures 700 including an input design structure 720 that is preferably processed by a design process. Design structure 720 may be a logical simulation design structure generated and processed by design process 710 to produce a logically equivalent functional representation of a hardware device. Design structure 720 may alternatively include data or program instructions that, when processed by design process 710, generate a functional representation of the physical structure of a hardware device. Whether representing functional or structural design features, design structure 720 may be generated using electronic computer-aided design, such as that implemented by a core developer/designer. When encoded on a machine-readable data transmission, gate array, or storage medium, design structure 720 may be accessed and processed by one or more hardware or software modules within design process 710 to simulate or otherwise functionally represent an electronic component, circuit, electronic or logic module, apparatus, device, or system such as those shown in FIGS. 3 and 4. As such, design structure 720 may include files or other data structures including human or machine-readable source code, compiled structures, and computer-executable code structures that, when processed by a design or simulation data processing system, functionally simulate or otherwise represent circuits or other levels of hardware logic design. Such data structures may include hardware-description language design entities or other data structures conforming to or compatible with lower-level HDL design languages such as Verilog and VHDL, or higher level design languages such as C or C++.

Design process 710 preferably employs and incorporates hardware or software modules for synthesizing, translating, or otherwise processing a design/simulation functional equivalent of the components, circuits, devices, or logic structures shown in FIGS. 3 and 4 to generate a Netlist 780 which may contain design structures such as design structure 720. Netlist 780 may comprise, for example, compiled or otherwise processed data structures representing a list of wires, discrete components, logic gates, control circuits, I/O devices, models, etc. that describe the connections to other elements and circuits in an integrated circuit design. Netlist 780 may be synthesized using an iterative process in which Netlist 780 is resynthesized one or more times depending on design specifications and parameters for the device. As with other design structure types described herein, Netlist 780 may be recorded on a machine-readable data storage medium or programmed into a programmable gate array. The medium may be a non-volatile storage medium such as a magnetic or optical disk drive, a programmable gate array, a compact flash, or other flash memory. Additionally, the medium may be a system or cache memory, buffer space, or electrically or optically conductive devices and materials on which data packets may be transmitted and intermediately stored via the internet, or other suitable networking means.

Design process 710 may include hardware and software modules for processing a variety of input data structure types including Netlist 780. Such data structure types may reside, for example, within library elements 730 and include a set of commonly used elements, circuits, and devices, including models, layouts, and symbolic representations, for a given manufacturing technology (e.g., different technology nodes, 32 nm, 45 nm, 90 nm, etc.). The data structure types may further include design specifications 740, characterization data 750, verification data 760, design rules 750, and test data files 785 which may include input test patterns, output test results, and other testing information. Design process 710 may further include, for example, standard mechanical design processes such as stress analysis, thermal analysis, mechanical event simulation, process simulation for operations such as casting, molding, and die press forming, etc. One of ordinary skill in the art of mechanical design can appreciate the extent of possible mechanical design tools and applications used in design process 710, without deviating from the scope and spirit of the invention. Design process 710 may also include modules for performing standard circuit design processes such as timing analysis, verification, design rule checking, place and route operations, etc.

Design process 710 employs and incorporates logic and physical design tools such as HDL compilers and simulation model build tools to process design structure 720 together with some or all of the depicted supporting data structures, along with any additional mechanical design or data, to generate a second design structure 790. Design structure 790 resides on a storage medium or programmable gate array in a data format used for the exchange of data of mechanical devices and structures (e.g., information stored on an IGES, DXF, Parasolid XT, JT, DRG, or any other suitable format for storing or rendering such mechanical design structures). Similar to design structure 720, design structure 790 preferably comprises one or more files, data structures, or other computer-encoded data or instructions that reside on transmission or data storage media and that, when processed by an ECAD system, generate a logically or otherwise functionally equivalent form of one or more of the embodiments of the invention shown in FIGS. 3 and 4. In one embodiment, design structure 790 may comprise a compiled, executable HDL simulation model that functionally simulates the devices shown in FIGS. 3 and 4.

Design structure 790 may also employ a data format used for the exchange of layout data of integrated circuits and/or symbolic data format (e.g., information stored in a GDSII, GL1, OASIS, map files, or any other suitable format for storing such design data structures). Design structure 790 may comprise information such as symbolic data, map files, test data files, design content files, manufacturing data, layout parameters, wires, levels of metal, vias, shapes, data for routing through the manufacturing line, and any other data required by a manufacturer or other designer/developer to produce a device or structure as described above and shown in FIGS. 3 and 4. Design structure 790 may then proceed to a state 795 where, for example, design structure 790 proceeds to tape-out, is released to manufacturing, is released to a mask house, is sent to another design house, is sent back to the customer, etc.

Although the present invention has been described in terms of specific embodiments, it is anticipated that alterations and modifications thereof may become apparent to those skilled in the art. Therefore, it is intended that the following claims be interpreted as covering all such alterations and modifications as fall within the true spirit and scope of the invention

What is claimed is:

1. A Static Random Access Memory (SRAM) device, comprising:
one or more SRAM cells, each SRAM cell further comprising a first and a second CMOS inverter that are cross-coupled, the first and second CMOS inverters each having a first switch and a second switch;
a reset circuit coupled to a first node of the first switch of the first CMOS inverter to drive the first CMOS inverter to output a logical high signal in a reset mode.

2. The SRAM device of claim 1, wherein the first switch is an N-channel Field Effect Transistor (NFET) and the second switch is a P-channel Field Effect Transistor.

3. The SRAM device of claim 1, wherein the reset circuit has a tristate inverter.

4. The SRAM device of claim 1, wherein the reset mode drives the first node of the first switch to Vdd.

5. The SRAM device of claim 1, wherein the reset circuit produces a reset output in the reset mode, the reset output resets the SRAM cell in the reset mode, and maintains the SRAM cell in a normal mode.

6. The SRAM device of claim 5, wherein the normal mode drives the first node of the first switch to GND.

7. The SRAM device of claim 1, wherein a second reset circuit is coupled to the second CMOS inverter to set the second CMOS inverter to output a logical high value.

8. A design structure tangibly embodied in a machine-readable storage medium used in a design process of an SRAM device, the design structure having elements that, when processed in a semiconductor manufacturing facility, produce an SRAM device that comprises:
one or more SRAM cells coupled to each other, each SRAM cell further comprising a first and a second CMOS inverter that are cross-coupled, the first and second CMOS inverters each having a P-channel Field Effect Transistor (PFET) and an N-channel Field Effect Transistor (NFET); and
a reset circuit coupled to a first node of the NFET in the first CMOS inverter of the one or more SRAM cells, the reset circuit drives a reset output to the first CMOS inverter to a reset mode to reset the SRAM cell and a normal mode to maintain operation of the SRAM cell.

9. The design structure of claim 8, wherein the SRAM cell is driven to Vdd in the reset mode.

10. The design structure of claim 8, wherein the SRAM cell is driven to GND in the normal mode.

11. The design structure of claim 8, wherein the reset circuit is coupled to one or SRAM cells with a column that couples to the first CMOS inverter.

12. The design structure of claim 8, wherein a second reset circuit is coupled to a first node of the NFET in the second CMOS inverter to output a logical high value.

13. A Static Random Access Memory (SRAM) device, comprising:
one or more SRAM cells further comprising:
a first CMOS inverter having a first N-type Field Effect Transistor (NFET) having a first node and a second node and a first P-type Field Effect Transistor (PFET) having a first node and a second node, the second node of the first NFET coupled to the second node of the first PFET, the first node of the PFET coupled to Vdd, a gate of the first NFET coupled to a gate of the first PFET;
a second CMOS inverter having a second NFET and a second PFET, a gate of the second NFET and a gate of the second PFET couples to the second node of the first NFET, an output of the second CMOS inverter connected to the gate of the first NFET; and
a reset circuit to couple with the first node of the first NFET, the reset circuit couples the first node of the first NFET to Vdd in a reset mode and couples the first node of the first NFET to GND in a normal mode.

14. The SRAM of claim 13, wherein the SRAM cell further comprises a pass gate controlled by a word line to couple a bit line to the gate of the first NFET.

15. The SRAM of claim 13, wherein the second NFET has a first node coupled to a second reset circuit and a second node coupled to the gate of the first NFET.

16. The SRAM of claim 15, wherein the second reset circuit couples the first node of the second NFET to Vdd in a second reset mode and couples the first node of the second NFET to GND in a second normal mode.

17. The SRAM of claim 16, wherein the SRAM uses the normal mode on the first CMOS inverter when using the second reset mode on the second CMOS inverter.

18. The SRAM of claim 16, wherein the SRAM uses the second normal mode on the second CMOS inverter when using the reset mode on the first CMOS inverter.

19. The SRAM of claim 16, wherein the reset circuit has a tristate inverter.

20. The SRAM of claim 17, wherein the first CMOS inverter is held floating that causes the SRAM cell to perform a power saving mode.
